(19) United States
(12) Patent Application Publication
(10) Pub. No.: US 2011/0000542 A1
(43) Pub. Date: Jan. 6, 2011

(54) HYBRID PHOTOVOLTAIC MODULES

(75) Inventor: Bharath Kumar Reddy Yellasiri, New Delhi (IN)

Correspondence Address: DAVID A. GUERRA;INTERNATIONAL PATENT GROUP, LLC, Suite 700, 1816 Crowchild Trail N.W., CALGARY, AB, T2M 3Y7, CA

(73) Assignee: MOSER BAER INDIA LIMITED, New Delhi (IN)

(21) Appl. No.: 12/570,324

(22) Filed: Sep. 30, 2009

(30) Foreign Application Priority Data
Jul. 1, 2009 (IN) 1563/CHE/2009

(51) Int. Cl. H01L 31/00; H01L 21/20; H05K 13/04

(52) U.S. Cl. 136/259; 136/263; 136/260; 438/73; 29/592.1; 257/E21.09

(57) ABSTRACT

A photovoltaic module (and a manufacturing method and system thereof) is provided. The photovoltaic module includes a base substrate, a nano-porous layer of an inorganic material deposited over the base substrate, and a photovoltaic layer of an organic material formed over the nano-porous layer. The nano-porous layer includes a plurality of nano-pores in which the organic material is deposited. The photovoltaic layer is capable of converting solar energy into electricity. The photovoltaic module also includes at least two electrodes capable of collecting electricity generated by the photovoltaic layer.

### CROSS-REFERENCE TO RELATED APPLICATION

This application claims the benefit of priority under 35 U.S.C 119 to co-pending India Patent Application No. 1563/CHE/2009 filed on Jul. 1, 2009. The entire disclosure of the prior application is incorporated herein by reference.

### BACKGROUND OF THE INVENTION

1. Field of the Invention

The embodiments herein relate, in general, to photovoltaic modules. More particularly, the embodiments relate to a method and system for manufacturing a photovoltaic module.

2. Description of the Prior Art

Photovoltaic modules are regarded as a good alternative source of energy. Most conventional photovoltaic modules are based on silicon, and are quite expensive. In an attempt to develop less expensive photovoltaic modules, photovoltaic modules based on polymeric and organic semiconductor materials have been devised. Hybrid photovoltaic modules incorporating inorganic materials in hetero-junction with organic materials have also emerged as an alternative to silicon-based photovoltaic modules. Unlike silicon-based photovoltaic modules, hybrid photovoltaic modules require specific architecture, due to nano-meter scale morphology and poor diffusion lengths of organic semiconductor materials. The architecture should enable better absorption of solar energy and efficient collection of charge carriers.

In a conventional bi-layer structure, an organic layer is formed over an inorganic layer. In this case, charge carriers are not able to reach electrodes due to poor diffusion length. In addition, the thickness of the organic layer is very less, due to which the absorption of solar energy is poor. In a conventional bulk hetero-junction structure, nano-particles of an inorganic material are mixed and arranged within a bulk of an organic material. In this case, the thickness of the organic material can be increased. As charge carriers travel through the nano-particles, any discontinuity in the arrangement of the nano-particles leads to carrier recombination. In addition, it is difficult to prepare the nano-particles and mix them with the organic material. Moreover, an appropriate ratio between the nano-particles and the organic material is critical for the performance of the photovoltaic module. Furthermore, such photovoltaic modules have much lower efficiencies, compared to silicon-based photovoltaic modules.

In another conventional technique, dye-sensitized photovoltaic modules were fabricated by absorbing a photovoltaic dye over a meso-porous film of Titanium Oxide (TiO₂). However, such meso-porous films are not suitable for organic materials. In yet another conventional technique, nano-particle structures have been grown on patterned substrate or templates using laser machining and anodization. However, such patterned substrates require patterning at a nano scale, thereby making them quite expensive. On the other hand, growing nano-particle structures on templates require several steps, thereby making the process complex and time-consuming.

In light of the foregoing discussion, there is a need for a photovoltaic module (and a manufacturing method and system thereof) that is suitable for mass manufacturing, has lower cost, has higher efficiency, and has ease of manufacturing, compared to conventional photovoltaic modules.

### SUMMARY OF THE INVENTION

In view of the foregoing disadvantages inherent in the known types of photovoltaic modules now present in the prior art, the present invention provides improved hybrid photovoltaic modules, and overcomes the above-mentioned disadvantages and drawbacks of the prior art. As such, the general purpose of the present invention, which will be described subsequently in greater detail, is to provide new and improved hybrid photovoltaic modules and method which has all the advantages of the prior art mentioned heretofore and many novel features that result in a hybrid photovoltaic modules which is not anticipated, rendered obvious, suggested, or even implied by the prior art, either alone or in any combination thereof.

An embodiment is to provide a photovoltaic module (and a manufacturing method and system thereof) that is suitable for mass manufacturing.

Another embodiment is to provide a photovoltaic module that has lower cost, has higher efficiency, and has ease of manufacturing, compared to conventional photovoltaic modules.

Embodiments herein provide a photovoltaic module that includes a base substrate, a nano-porous layer of an inorganic material deposited over the base substrate, and a photovoltaic layer of an organic material formed over the nano-porous layer. The nano-porous layer includes a plurality of nano-pores in which the organic material is deposited. The photovoltaic layer is capable of converting solar energy into electricity. The photovoltaic module also includes at least two electrodes capable of collecting electricity generated by the photovoltaic layer.

In accordance with an embodiment herein, the nano-porous layer is deposited by chemical bath deposition of the inorganic material. In accordance with another embodiment herein, the nano-porous layer is deposited by ultrasonic-assisted chemical bath deposition of the inorganic material. In accordance with yet another embodiment herein, the nano-porous layer is deposited by microwave-assisted chemical bath deposition of the inorganic material. Examples of the inorganic material include, but are not limited to, Cadmium Sulfide (CdS), Cadmium Telluride (CdTe), Copper Indium Diselenide (CuInSe₂), Copper Indium/Gallium Selenide (CIGS), Stannous Sulfide (SnS), Copper Zinc Tin Sulfide (Cu₂ZnSnS₄), Copper Aluminum Tin Selenide (CuAlSnSe₄), and Lead Selenide (PbSe).

In an embodiment herein, the thickness of the nano-porous layer ranges from 100 nm to 200 nm.

In accordance with an embodiment herein, the size of the nano-pores depends on the molecular size of the organic material used. In an embodiment herein, the size of the nano-pores ranges from 100 nm to 200 nm, and the molecular size of the organic material ranges from 100 nm to 200 nm. Examples of the organic material include, but are not limited to, Poly[5,5-bis(3-dodecyl-2-thienyl)-2,2-bithiophene (PQT-12), Poly(3-hexylthiophene) (P3HT), Copper Phthalocyanine (CuPc), Zinc Phthalocyanine (ZnPc), Poly[2-methoxy-5-(3,7-dimethyloctyloxy)]-1,4-phenylene vinylene (MDMO:PPV), and Poly carbazole.

In addition, the size of the nano-pores may be varied as required, for example, by using different inorganic materials, by using different complexing agents and surfactants, and by varying the power and/or frequency of the ultrasonic and/or microwave assistance.

The surface area of an interface between the nano-porous layer and the photovoltaic layer is large. Consequently, charge carrier separation at the interface is higher. Therefore, the photovoltaic module has higher efficiency, compared to conventional photovoltaic modules.

In addition, the nano-porous layer is formed by a single-step, simple and inexpensive chemical bath deposition process. Therefore, the photovoltaic module is easy to manufacture, and is suitable for mass manufacturing, compared to conventional photovoltaic modules. Furthermore, the photovoltaic module so manufactured has lower cost, compared to conventional photovoltaic modules.

There has thus been outlined, rather broadly, the more important features of the invention in order that the detailed description thereof that follows may be better understood and in order that the present contribution to the art may be better appreciated.

Numerous objects, features and advantages of the present invention will be readily apparent to those of ordinary skill in the art upon a reading of the following detailed description of presently preferred, but nonetheless illustrative, embodiments of the present invention when taken in conjunction with the accompanying drawings. In this respect, before explaining the current embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of descriptions and should not be regarded as limiting.

As such, those skilled in the art will appreciate that the conception, upon which this disclosure is based, may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

These together with other objects of the invention, along with the various features of novelty that characterize the invention, are pointed out with particularity in the claims annexed to and forming a part of this disclosure. For a better understanding of the invention, its operating advantages and the specific objects attained by its uses, reference should be had to the accompanying drawings and descriptive matter in which there are illustrated preferred embodiments of the invention.

### BRIEF DESCRIPTION OF THE DRAWINGS

Embodiments herein will hereinafter be described in conjunction with the appended drawings provided to illustrate and not to limit the scope of the claims, wherein like designations denote like elements, and in which:

FIG. 1 is a schematic diagram depicting a photovoltaic module, in accordance with an embodiment herein;

FIG. 2 depicts a system for manufacturing a photovoltaic module, in accordance with an embodiment herein;

FIG. 3 depicts a system for manufacturing a photovoltaic module, in accordance with another embodiment herein;

FIG. 4 illustrates a method of manufacturing a photovoltaic module, in accordance with an embodiment herein;

FIG. 5 illustrates a method of manufacturing a photovoltaic module, in accordance with another embodiment herein;

FIG. 6 illustrates a method of manufacturing a system for generating electricity from solar energy, in accordance with an embodiment herein;

FIG. 7 illustrates a method of manufacturing a system for generating electricity from solar energy, in accordance with another embodiment herein;

FIG. 8 illustrates a system for generating electricity from solar energy, in accordance with an embodiment herein; and

FIG. 9 illustrates a system for generating electricity from solar energy, in accordance with another embodiment herein.

The same reference numerals refer to the same parts throughout the various figures.

### DESCRIPTION OF THE PREFERRED EMBODIMENT

As used in the specification and claims, the singular forms “a”, “an” and “the” include plural references unless the context clearly dictates otherwise. For example, the term “a photovoltaic module” may include a plurality of photovoltaic modules unless the context clearly dictates otherwise.

Embodiments herein provide a photovoltaic module, a method and system for manufacturing the photovoltaic module, a system for generating electricity from solar energy, and a method of manufacturing the system for generating electricity from solar energy. In the description of the embodiments herein, numerous specific details are provided, such as examples of components and/or mechanisms, to provide a thorough understanding of embodiments herein. One skilled in the relevant art will recognize, however, that an embodiment herein can be practiced without one or more of the specific details, or with other apparatus, systems, assemblies, methods, components, materials, parts, and/or the like. In other instances, well-known structures, materials, or operations are not specifically shown or described in detail to avoid obscuring aspects of embodiments herein.

### GLOSSARY

Photovoltaic module: A photovoltaic module is a packaged interconnected assembly of a nano-porous layer of an inorganic material and a photovoltaic layer of an organic material, which converts solar energy into electricity by the photovoltaic effect.

Base substrate: A base substrate is a term used to describe a base member of the photovoltaic module on which the nano-porous layer is formed.

Nano-porous layer: A nano-porous layer is a layer in which a plurality of nano-pores are formed. The size of the nano-pores may, for example, range from 100 nm to 200 nm. In an embodiment herein, a nano-porous layer of an inorganic material is deposited by chemical bath deposition.

Complexing agent: A complexing agent is a substance capable of forming a complex compound with another substance in a solution. For example, a complexing agent may combine with unwanted ions present in a chemical bath solution to form complex compounds, thereby diminishing the reactivity of the unwanted ions. This enhances the rate and the yield of the chemical bath deposition.

Surfactants: A surfactant increases the viscosity of the chemical bath solution, thereby hindering free movement of reacted particles over a surface on which a nano-porous layer is to be deposited. This leads to formation of a nano-porous layer over that surface.

Photovoltaic layer: A photovoltaic layer is a layer of a photovoltaic material that is capable of converting solar energy into electricity.

Electrode: Electrodes are electrically-conductive structures that are used to collect electricity generated by the photovoltaic layer.

Transparent member: A transparent member is an optically clear member placed over the photovoltaic module to seal and protect the photovoltaic module from environmental damage.

Anti-reflective coating: An anti-reflective coating is a coating over the transparent member that reduces loss of solar energy incident on the photovoltaic module.

Laminate: A laminate is a polymeric material that is used to encapsulate the entire assembly of the base substrate, the nano-porous layer, the photovoltaic layer and the electrodes.

First electrode-forming unit: A first electrode-forming unit is adapted to form a first electrode over a first surface of a base substrate.

Nano-porous-layer-depositing unit: A nano-porous-layer-depositing unit is adapted to deposit a nano-porous layer of an inorganic material over the first electrode. The nano-porous-layer-forming unit may, for example, perform chemical bath deposition, ultrasonic-assisted chemical bath deposition, or microwave-assisted chemical bath deposition.

Ultrasonic-assisted chemical bath deposition: An ultrasonic-assisted chemical bath deposition process is a chemical bath process that is assisted by a pre-defined ultrasonic power and a pre-defined ultrasonic frequency.

Microwave-assisted chemical bath deposition: A microwave-assisted chemical bath deposition process is a chemical bath process that is assisted by a pre-defined microwave power.

Photovoltaic-layer-forming unit: A photovoltaic-layer-forming unit is adapted to form a photovoltaic layer of an organic material over the nano-porous layer.

Second electrode-forming unit: A second electrode-forming unit is adapted to form a second electrode over the photovoltaic layer.

Positioning unit: A positioning unit is adapted to position a transparent member over the second electrode.

Encapsulating unit: An encapsulating unit is adapted to encapsulate the base substrate, the nano-porous layer, the photovoltaic layer and the electrodes with a laminate.

Power-consuming unit: A power-consuming unit is adapted to consume the charge generated by the photovoltaic module. The power-consuming unit may also store the charge.

AC Load: An AC Load is a device that operates on Alternating Current (AC).

DC Load: A DC Load is a device that operates on Direct Current (DC).

Charge controller: A charge controller is adapted to control the amount of charge consumed by the power-consuming unit.

Inverter: An inverter is adapted to convert electricity from a first form to a second form. For example, the inverter may convert electricity from AC to DC and vice-versa.

The photovoltaic module includes a base substrate, a nano-porous layer of an inorganic material deposited over the base substrate, and a photovoltaic layer of an organic material formed over the nano-porous layer. The nano-porous layer includes a plurality of nano-pores in which the organic material is deposited. The photovoltaic layer is capable of converting solar energy into electricity. The photovoltaic module also includes at least two electrodes capable of collecting electricity generated by the photovoltaic layer.

In accordance with an embodiment herein, the nano-porous layer is deposited by chemical bath deposition of the inorganic material. In accordance with another embodiment herein, the nano-porous layer is deposited by ultrasonic-assisted chemical bath deposition of the inorganic material. In accordance with yet another embodiment herein, the nano-porous layer is deposited by microwave-assisted chemical bath deposition of the inorganic material. Examples of the inorganic material include, but are not limited to, Cadmium Sulfide (CdS), Cadmium Telluride (CdTe), Copper Indium Diselenide (CuInSe₂), Copper Indium/Gallium Selenide (CIGS), Stannous Sulfide (SnS), Copper Zinc Tin Sulfide (Cu₂ZnSnS₄), Copper Aluminum Tin Selenide (CuAlSnSe₄), and Lead Selenide (PbSe).

In accordance with an embodiment herein, the photovoltaic layer is formed by spin coating the organic material over the nano-porous layer. Examples of the organic material include, but are not limited to, Poly[5,5-bis(3-dodecyl-2-thienyl)-2,2-bithiophene (PQT-12), Poly(3-hexylthiophene) (P3HT), Copper Phthalocyanine (CuPc), Zinc Phthalocyanine (ZnPc), Poly[2-methoxy-5-(3,7-dimethyloctyloxy)]-1,4-phenylene vinylene (MDMO:PPV), and Poly carbazole.

In an embodiment herein, the thickness of the nano-porous layer ranges from 100 nm to 200 nm.

In accordance with an embodiment herein, the size of the nano-pores depends on the molecular size of the organic material used. In an embodiment herein, the size of the nano-pores ranges from 100 nm to 200 nm, and the molecular size of the organic material ranges from 100 nm to 200 nm.

In accordance with an embodiment herein, a first electrode from the at least two electrodes includes a coating of a first conductive material formed in between the base substrate and the nano-porous layer, while a second electrode from the at least two electrodes includes a coating of a second conductive material formed over the photovoltaic layer.

In accordance with an embodiment herein, the photovoltaic module further includes a transparent member positioned over the photovoltaic layer. The transparent member is coated with an anti-reflective coating to reduce loss of solar energy incident on the photovoltaic module, in accordance with an embodiment herein.

In accordance with an embodiment herein, the photovoltaic module also includes a laminate encapsulating the base substrate, the nano-porous layer, the photovoltaic layer and the at least two electrodes. The laminate holds the photovoltaic module together, and encapsulates various components of the photovoltaic module hermetically.

The photovoltaic module can be used in various applications. For example, an array of photovoltaic modules may be used to generate electricity on a large scale for grid power supply. In another example, photovoltaic modules may be used to generate electricity on a small scale for home/office use. Alternatively, photovoltaic modules may be used to generate electricity for stand-alone electrical devices, such as automobiles and spacecraft. Details of these applications have been provided in conjunction with drawings below.

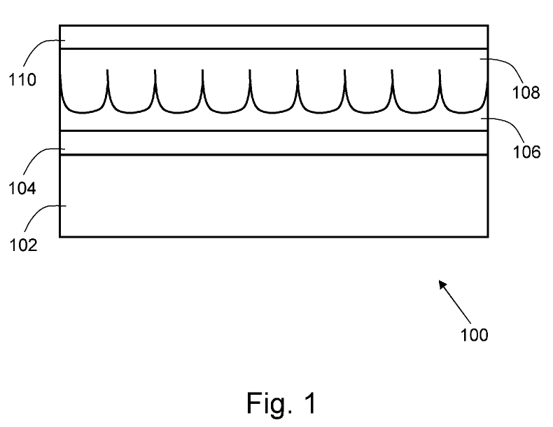

FIG. 1 is a schematic diagram depicting a photovoltaic module 100, in accordance with an embodiment herein. Photovoltaic module 100 includes a base substrate 102, a first electrode 104 formed over base substrate 102, a nano-porous layer 106 deposited over first electrode 104, a photovoltaic layer 108 formed over nano-porous layer 106, and a second electrode 110 formed over photovoltaic layer 108.

Base substrate 102 provides support to photovoltaic module 100. Base substrate 102 may, for example, be made of any material that is tolerant to moisture, Ultra Violet (UV) radiation, abrasion, and natural temperature variations. Examples of such materials include, but are not limited to, glass, plastics and suitable polycarbonates.

First electrode 104 is formed on a first surface of base substrate 102, as shown in FIG. 1. The first surface of base substrate 102 may, for example, be electrically insulated. In accordance with an embodiment herein, first electrode 104 includes a coating of a first conductive material formed over the first surface of base substrate 102. The first conductive material may, for example, be a transparent conductive oxide, such as Indium Tin Oxide (ITO) and Aluminum-doped Zinc Oxide. Alternatively, the first conductive material may be Poly(3,4-ethylenedioxythiophene) (PEDOT), Poly(3,4-ethylenedioxythiophene)poly(styrenesulfonate) (PEDOT:PSS), and Poly Aniline (PANI).

Nano-porous layer 106 is deposited over first electrode 104 by chemical bath deposition of an inorganic material, in accordance with an embodiment herein. In accordance with another embodiment herein, nano-porous layer 106 is deposited by ultrasonic-assisted chemical bath deposition of the inorganic material. In accordance with yet another embodiment herein, nano-porous layer 106 is deposited by microwave-assisted chemical bath deposition of the inorganic material. Examples of the inorganic material include, but are not limited to, Cadmium Sulfide (CdS), Cadmium Telluride (CdTe), Copper Indium Diselenide (CuInSe₂), Copper Indium/Gallium Selenide (CIGS), Stannous Sulfide (SnS), Copper Zinc Tin Sulfide (Cu₂ZnSnS₄), Copper Aluminum Tin Selenide (CuAlSnSe₄), and Lead Selenide (PbSe). In an embodiment herein, the thickness of nano-porous layer 106 ranges from 100 nm to 200 nm.

Nano-porous layer 106 includes a plurality of nano-pores in which an organic material is deposited to form photovoltaic layer 108. In an embodiment herein, the size of the nano-pores ranges from 100 nm to 200 nm, and the molecular size of the organic material ranges from 100 nm to 200 nm. Examples of the organic material include, but are not limited to, Poly[5,5-bis(3-dodecyl-2-thienyl)-2,2-bithiophene (PQT-12), Poly(3-hexylthiophene) (P3HT), Copper Phthalocyanine (CuPc), Zinc Phthalocyanine (ZnPc), Poly[2-methoxy-5-(3,7-dimethyloctyloxy)]-1,4-phenylene vinylene (MDMO:PPV), and Poly carbazole.

Photovoltaic layer 108 is capable of converting solar energy into electricity. First electrode 104 and second electrode 110 are capable of collecting electricity generated by photovoltaic layer 108. In accordance with an embodiment herein, second electrode 110 includes a coating of a second conductive material formed over photovoltaic layer 108. Examples of the second conductive material include, but are not limited to, silver, aluminum, and calcium.

In accordance with an embodiment herein, photovoltaic module 100 further includes a transparent member (not shown in FIG. 1) positioned over second electrode 110. The transparent member protects photovoltaic layer 108 and second electrode 110 from environmental damage, while allowing electromagnetic radiation falling on its surface to pass to photovoltaic layer 108. The transparent member may, for example, be a toughened glass with low iron content, or be made of a polymeric material. In addition, the transparent member may be coated with an anti-reflective coating, so that reflection occurring at a medium boundary between air and the transparent member is minimized.

In accordance with an embodiment herein, photovoltaic module 100 also includes a laminate (not shown in FIG. 1) encapsulating base substrate 102, first electrode 104, nano-porous layer 106, photovoltaic layer 108 and second electrode 110. The laminate holds photovoltaic module 100 together, and encapsulates various components of photovoltaic module 100 hermetically. The laminate also protects photovoltaic module 100 from moisture, abrasion, and natural temperature variations.

When electromagnetic radiation falls over photovoltaic layer 108, electron-hole pairs are created in photovoltaic layer 108. Electrons and holes are separated at an interface between nano-porous layer 106 and photovoltaic layer 108, thereby generating a voltage. When a load is connected across first electrode 104 and second electrode 110, the generated voltage drives current, thereby producing electricity.

It should be noted here that photovoltaic module 100 is not limited to a specific shape, size, type, material, or arrangement of its components. FIG. 1 is merely an example, which should not unduly limit the scope of the claims herein. One of ordinary skill in the art would recognize many variations, alternatives, and modifications of embodiments herein.

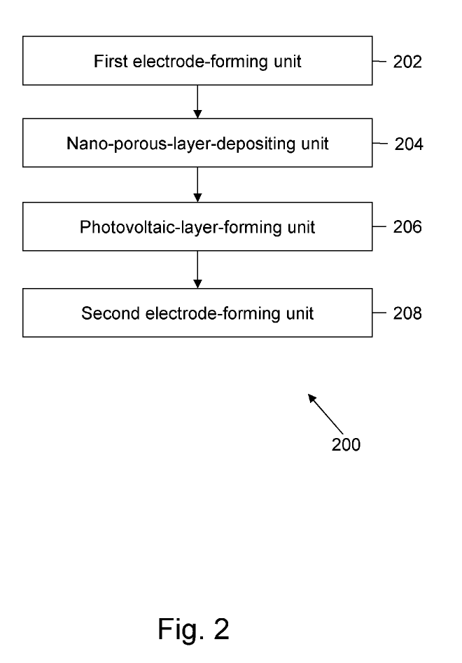

FIG. 2 depicts a system 200 for manufacturing a photovoltaic module, in accordance with an embodiment herein. System 200 includes a first electrode-forming unit 202, a nano-porous-layer-depositing unit 204, a photovoltaic-layer-forming unit 206, and a second electrode-forming unit 208.

First electrode-forming unit 202 is adapted to form a first electrode over a first surface of a base substrate. In accordance with an embodiment herein, first electrode-forming unit 202 is adapted to form a coating of a first conductive material over the first surface of the base substrate. Examples of the first conductive material include, but are not limited to, Indium Tin Oxide (ITO), Aluminum-doped Zinc Oxide, Poly(3,4-ethylenedioxythiophene) (PEDOT), Poly(3,4-ethylenedioxythiophene) poly(styrenesulfonate) (PEDOT:PSS), and Poly Aniline (PANI). First electrode-forming unit 202 may, for example, be adapted to perform vapor deposition, screen printing or spin coating depending on the first conductive material used.

Nano-porous-layer-depositing unit 204 is adapted to deposit a nano-porous layer of an inorganic material over the first electrode, using chemical bath deposition, in accordance with an embodiment herein. In accordance with another embodiment herein, nano-porous-layer-depositing unit 204 is adapted to perform ultrasonic-assisted chemical bath deposition of the inorganic material over the first electrode. In accordance with yet another embodiment herein, nano-porous-layer-depositing unit 204 is adapted to perform microwave-assisted chemical bath deposition of the inorganic material over the first electrode. Examples of the inorganic material include, but are not limited to, Cadmium Sulfide (CdS), Cadmium Telluride (CdTe), Copper Indium Diselenide (CuInSe₂), Copper Indium/Gallium Selenide (CIGS), Stannous Sulfide (SnS), Copper Zinc Tin Sulfide (Cu₂ZnSnS₄), Copper Aluminum Tin Selenide (CuAlSnSe₄), and Lead Selenide (PbSe).

Nano-porous-layer-depositing unit 204 may, for example, use various complexing agents and surfactants during the process of chemical bath deposition. Complexing agents combine with unwanted ions present in a chemical bath solution to form complex compounds, thereby diminishing the reactivity of the unwanted ions. This enhances the rate and the yield of the chemical bath deposition. Examples of complexing agents that may be used include, but are not limited to, Ethylenediaminetetraacetic acid (EDTA), Sodium Citrate, Hydrazine, Triethylamine, and Triethanolamine. Surfactants increase the viscosity of the chemical bath solution, thereby hindering free movement of reacted particles over the surface of the first electrode. This leads to formation of the nano-porous layer over the surface of the first electrode. An example of a surfactant that may be used includes, but is not limited to, Puron.

The nano-porous layer so formed includes a plurality of nano-pores. In accordance with an embodiment herein, nano-porous-layer-depositing unit 204 is adapted to control the thickness of the nano-porous layer and/or the size of the nano-pores. In accordance with an embodiment herein, nano-porous-layer-depositing unit 204 is adapted to form the nano-pores with sizes ranging from 100 nm to 200 nm. The size of the nano-pores may be controlled, for example, by using different inorganic materials, by using different complexing agents and surfactants, and by varying the power and/or frequency of the ultrasonic and/or microwave assistance.

Photovoltaic-layer-forming unit 206 is adapted to form a photovoltaic layer of an organic material over the nano-porous layer. Accordingly, the organic material is deposited into the nano-pores. Examples of the organic material include, but are not limited to, Poly[5,5-bis(3-dodecyl-2-thienyl)-2,2-bithiophene (PQT-12), Poly(3-hexylthiophene) (P3HT), Copper Phthalocyanine (CuPc), Zinc Phthalocyanine (ZnPc), Poly[2-methoxy-5-(3,7-dimethyloctyloxy)]-1,4-phenylene vinylene (MDMO:PPV), and Poly carbazole. Photovoltaic-layer-forming unit 206 may, for example, be adapted to perform spin coating.

Second electrode-forming unit 208 is adapted to form a second electrode over the photovoltaic layer. In accordance with an embodiment herein, second electrode-forming unit 208 is adapted to form a coating of a second conductive material over the photovoltaic layer. Examples of the second conductive material include, but are not limited to, silver, aluminum, and calcium. Second electrode-forming unit 208 may, for example, be adapted to perform vapor deposition or screen printing.

As mentioned above, the photovoltaic layer is capable of converting solar energy into electricity. The first electrode and the second electrode are capable of collecting electricity generated by the photovoltaic layer.

FIG. 2 is merely an example, which should not unduly limit the scope of the claims herein. One of ordinary skill in the art would recognize many variations, alternatives, and modifications of embodiments herein.

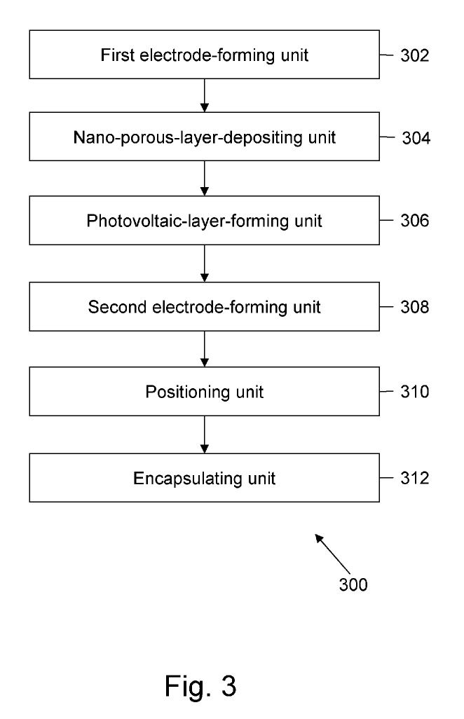

FIG. 3 depicts a system 300 for manufacturing a photovoltaic module, in accordance with another embodiment herein. System 300 includes a first electrode-forming unit 302, a nano-porous-layer-depositing unit 304, a photovoltaic-layer-forming unit 306, a second electrode-forming unit 308, a positioning unit 310, and an encapsulating unit 312.

First electrode-forming unit 302 is adapted to form a first electrode over a first surface of a base substrate. In accordance with an embodiment herein, first electrode-forming unit 302 is adapted to form a coating of a first conductive material over the first surface of the base substrate. Examples of the first conductive material include, but are not limited to, Indium Tin Oxide (ITO), Aluminum-doped Zinc Oxide, Poly(3,4-ethylenedioxythiophene) (PEDOT), Poly(3,4-ethylenedioxythiophene) poly(styrenesulfonate) (PEDOT:PSS), and Poly Aniline (PANI). First electrode-forming unit 302 may, for example, be adapted to perform vapor deposition, screen printing or spin coating depending on the first conductive material used.

Nano-porous-layer-depositing unit 304 is adapted to deposit a nano-porous layer of an inorganic material over the first electrode, using chemical bath deposition, in accordance with an embodiment herein. In accordance with another embodiment herein, nano-porous-layer-depositing unit 304 is adapted to perform ultrasonic-assisted chemical bath deposition of the inorganic material over the first electrode. In accordance with yet another embodiment herein, nano-porous-layer-depositing unit 304 is adapted to perform microwave-assisted chemical bath deposition of the inorganic material over the first electrode. Examples of the inorganic material include, but are not limited to, Cadmium Sulfide (CdS), Cadmium Telluride (CdTe), Copper Indium Diselenide (CuInSe₂), Copper Indium/Gallium Selenide (CIGS), Stannous Sulfide (SnS), Copper Zinc Tin Sulfide (Cu₂ZnSnS₄), Copper Aluminum Tin Selenide (CuAlSnSe₄), and Lead Selenide (PbSe).

Nano-porous-layer-depositing unit 304 may, for example, use various complexing agents and surfactants during the process of chemical bath deposition. Examples of complexing agents that may be used include, but are not limited to, Ethylenediaminetetraacetic acid (EDTA), Sodium Citrate, Hydrazine, Triethylamine, and Triethanolamine. An example of a surfactant that may be used includes, but is not limited to, Puron.

The nano-porous layer so formed includes a plurality of nano-pores. In accordance with an embodiment herein, nano-porous-layer-depositing unit 304 is adapted to control the thickness of the nano-porous layer and/or the size of the nano-pores. In accordance with an embodiment herein, nano-porous-layer-depositing unit 304 is adapted to form the nano-pores with sizes ranging from 100 nm to 200 nm. The size of the nano-pores may be controlled, for example, by using different inorganic materials, by using different complexing agents and surfactants, and by varying the power and/or frequency of the ultrasonic and/or microwave assistance.

Photovoltaic-layer-forming unit 306 is adapted to form a photovoltaic layer of an organic material over the nano-porous layer. Accordingly, the organic material is deposited into the nano-pores. Examples of the organic material include, but are not limited to, Poly[5,5-bis(3-dodecyl-2-thienyl)-2,2-bithiophene (PQT-12), Poly(3-hexylthiophene) (P3HT), Copper Phthalocyanine (CuPc), Zinc Phthalocyanine (ZnPc), Poly[2-methoxy-5-(3,7-dimethyloctyloxy)]-1,4-phenylene vinylene (MDMO:PPV), and Poly carbazole. Photovoltaic-layer-forming unit 306 may, for example, be adapted to perform spin coating.

Second electrode-forming unit 308 is adapted to form a second electrode over the photovoltaic layer. In accordance with an embodiment herein, second electrode-forming unit 308 is adapted to form a coating of a second conductive material over the photovoltaic layer. Examples of the second conductive material include, but are not limited to, silver, aluminum, and calcium. Second electrode-forming unit 308 may, for example, be adapted to perform vapor deposition or screen printing.

As mentioned above, the photovoltaic layer is capable of converting solar energy into electricity. The first electrode and the second electrode are capable of collecting electricity generated by the photovoltaic layer.

Positioning unit 310 is adapted to position a transparent member over the second electrode. Positioning unit 310 may, for example, be a pick-and-place unit that picks the transparent member, and aligns and places the transparent member over the second electrode.

Encapsulating unit 312 is adapted to encapsulate the base substrate, the nano-porous layer, the photovoltaic layer and the at least two electrodes with a laminate. Encapsulating unit 312 may, for example, include a laminator that laminates various components of the photovoltaic module with the laminate at a prescribed temperature and/or pressure in a vacuum environment. The vacuum environment ensures that no air bubbles are formed within the laminate. The laminate may, for example, be any material that is tolerant to moisture, abrasion, and natural temperature variations.

FIG. 3 is merely an example, which should not unduly limit the scope of the claims herein. One of ordinary skill in the art would recognize many variations, alternatives, and modifications of embodiments herein.

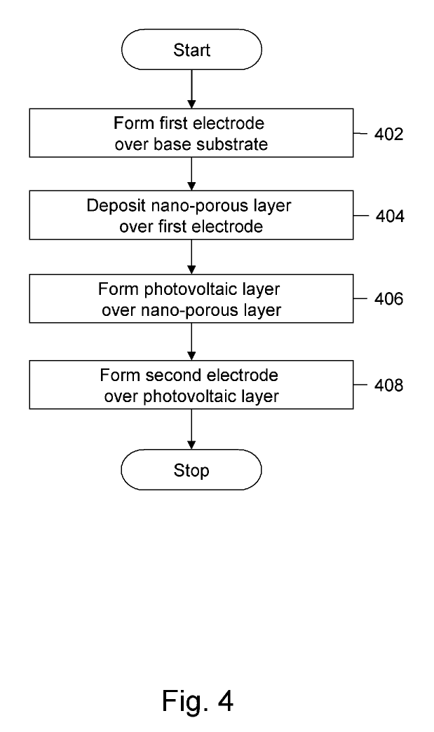

FIG. 4 illustrates a method of manufacturing a photovoltaic module, in accordance with an embodiment herein. The method is illustrated as a collection of steps in a logical flow diagram, which represents a sequence of steps that can be implemented in hardware, software, or a combination thereof.

At step 402, a first electrode is formed over a first surface of a base substrate. In accordance with an embodiment herein, the first electrode is formed by coating a first conductive material over the first surface of the base substrate. Examples of the first conductive material include, but are not limited to, Indium Tin Oxide (ITO), Aluminum-doped Zinc Oxide, Poly(3,4-ethylenedioxythiophene) (PEDOT), Poly(3,4-ethylenedioxythiophene)poly(styrenesulfonate) (PEDOT:PSS), and Poly Aniline (PANI). Step 402 may, for example, be performed by vapor deposition, screen printing or spin coating depending on the first conductive material used.

At step 404, a nano-porous layer of an inorganic material is deposited over the first electrode. In accordance with an embodiment herein, step 404 is performed by chemical bath deposition of the inorganic material. In accordance with another embodiment herein, step 404 is performed by ultrasonic-assisted chemical bath deposition of the inorganic material. In accordance with yet another embodiment herein, step 404 is performed by microwave-assisted chemical bath deposition of the inorganic material. Examples of the inorganic material include, but are not limited to, Cadmium Sulfide (CdS), Cadmium Telluride (CdTe), Copper Indium Diselenide (CuInSe₂), Copper Indium/Gallium Selenide (CIGS), Stannous Sulfide (SnS), Copper Zinc Tin Sulfide (Cu₂ZnSnS₄), Copper Aluminum Tin Selenide (CuAlSnSe₄), and Lead Selenide (PbSe). The nano-porous layer so formed includes a plurality of nano-pores.

Various complexing agents and surfactants may be used during the process of chemical bath deposition, at step 404. Examples of complexing agents that may be used include, but are not limited to, Ethylenediaminetetraacetic acid (EDTA), Sodium Citrate, Hydrazine, Triethylamine, and Triethanolamine. An example of a surfactant that may be used includes, but is not limited to, Puron.

In accordance with an embodiment herein, step 404 includes a sub-step of controlling the thickness of the nano-porous layer and/or the size of the nano-pores. In accordance with an embodiment herein, the size of the nano-pores formed at step 404 ranges from 100 nm to 200 nm. The size of the nano-pores may be controlled, for example, by using different inorganic materials, by using different complexing agents and surfactants, and by varying the power and/or frequency of the ultrasonic and/or microwave assistance.

At step 406, a photovoltaic layer of an organic material is formed over the nano-porous layer. Accordingly, the organic material is deposited into the nano-pores. Examples of the organic material include, but are not limited to, Poly[5,5-bis(3-dodecyl-2-thienyl)-2,2-bithiophene (PQT-12), Poly(3-hexylthiophene) (P3HT), Copper Phthalocyanine (CuPc), Zinc Phthalocyanine (ZnPc), Poly[2-methoxy-5-(3,7-dimethyloctyloxy)]-1,4-phenylene vinylene (MDMO:PPV), and Poly carbazole. Step 406 may, for example, be performed by spin coating.

At step 408, a second electrode is formed over the photovoltaic layer. In accordance with an embodiment herein, the second electrode is formed by coating a second conductive material over the photovoltaic layer. Examples of the second conductive material include, but are not limited to, silver, aluminum, and calcium. Step 408 may, for example, be performed by vapor deposition or screen printing.

As mentioned above, the photovoltaic layer is capable of converting solar energy into electricity. The first electrode and the second electrode are capable of collecting electricity generated by the photovoltaic layer.

It should be noted here that steps 402-408 are only illustrative and other alternatives can also be provided where steps are added, one or more steps are removed, or one or more steps are provided in a different sequence without departing from the scope of the claims herein.

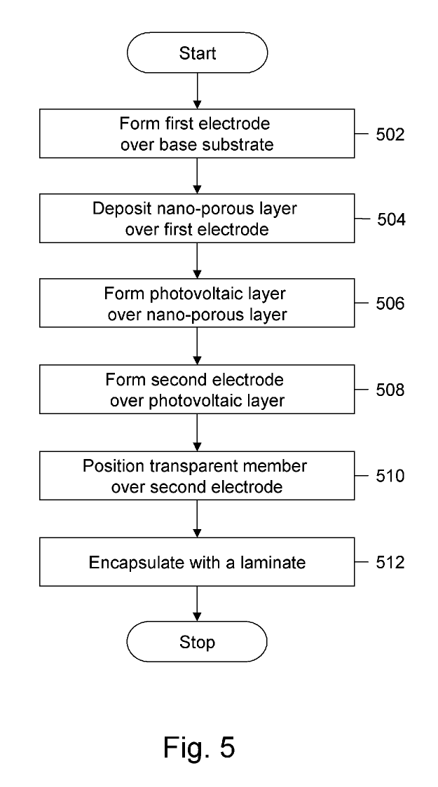

FIG. 5 illustrates a method of manufacturing a photovoltaic module, in accordance with another embodiment herein. The method is illustrated as a collection of steps in a logical flow diagram, which represents a sequence of steps that can be implemented in hardware, software, or a combination thereof.

At step 502, a first electrode is formed over a first surface of a base substrate. In accordance with an embodiment herein, the first electrode is formed by coating a first conductive material over the first surface of the base substrate. Examples of the first conductive material include, but are not limited to, Indium Tin Oxide (ITO), Aluminum-doped Zinc Oxide, Poly(3,4-ethylenedioxythiophene) (PEDOT), Poly(3,4-ethylenedioxythiophene)poly(styrenesulfonate) (PEDOT:PSS), and Poly Aniline (PANI). Step 502 may, for example, be performed by vapor deposition, screen printing or spin coating depending on the first conductive material used.

At step 504, a nano-porous layer of an inorganic material is deposited over the first electrode. In accordance with an embodiment herein, step 504 is performed by chemical bath deposition of the inorganic material. In accordance with another embodiment herein, step 504 is performed by ultrasonic-assisted chemical bath deposition of the inorganic material. In accordance with yet another embodiment herein, step 504 is performed by microwave-assisted chemical bath deposition of the inorganic material. Examples of the inorganic material include, but are not limited to, Cadmium Sulfide (CdS), Cadmium Telluride (CdTe), Copper Indium Diselenide (CuInSe₂), Copper Indium/Gallium Selenide (CIGS), Stannous Sulfide (SnS), Copper Zinc Tin Sulfide (Cu₂ZnSnS₄), Copper Aluminum Tin Selenide (CuAlSnSe₄), and Lead Selenide (PbSe). The nano-porous layer so formed includes a plurality of nano-pores.

Various complexing agents and surfactants may be used during the process of chemical bath deposition, at step 504. Examples of complexing agents that may be used include, but are not limited to, Ethylenediaminetetraacetic acid (EDTA), Sodium Citrate, Hydrazine, Triethylamine, and Triethanolamine. An example of a surfactant that may be used includes, but is not limited to, Puron.

In accordance with an embodiment herein, step 504 includes a sub-step of controlling the thickness of the nano-porous layer and/or the size of the nano-pores. In accordance with an embodiment herein, the size of the nano-pores formed at step 504 ranges from 100 nm to 200 nm. The size of the nano-pores may be controlled, for example, by using different inorganic materials, by using different complexing agents and surfactants, and by varying the power and/or frequency of the ultrasonic and/or microwave assistance.

Consider, for example, that a nano-porous layer is deposited by chemical bath deposition of Cadmium Sulfide (CdS). Triethanolamine may be used as a complexing agent, while Puron may be used as a surfactant. The following reactions may take place in the chemical bath deposition:

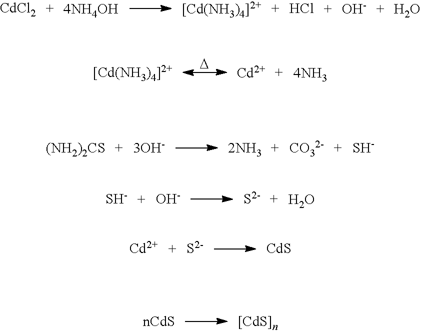

In accordance with an embodiment herein, the process of chemical bath deposition is performed without any ultrasonic or microwave assistance. In such a case, the time taken in the deposition of the nano-porous layer is approximately 30 minutes.

In accordance with another embodiment herein, the process of chemical bath deposition is performed with ultrasonic assistance. In such a case, power ranging from 30 watts to 300 watts and a frequency of 40 kilo Hertz may be applied. The time taken in the deposition of the nano-porous layer is approximately 30 minutes in ultrasonic-assisted chemical bath deposition.

In accordance with yet another embodiment herein, the process of chemical bath deposition is performed with microwave assistance. In such a case, power of approximately 200 watts may be applied. The time taken in the deposition of the nano-porous layer is approximately 10 minutes in microwave-assisted chemical bath deposition.

At step 506, a photovoltaic layer of an organic material is formed over the nano-porous layer. Accordingly, the organic material is deposited into the nano-pores. Examples of the organic material include, but are not limited to, Poly[5,5-bis(3-dodecyl-2-thienyl)-2,2-bithiophene (PQT-12), Poly(3-hexylthiophene) (P3HT), Copper Phthalocyanine (CuPc), Zinc Phthalocyanine (ZnPc), Poly[2-methoxy-5-(3,7-dimethyloctyloxy)]-1,4-phenylene vinylene (MDMO:PPV), and Poly carbazole. Step 506 may, for example, be performed by spin coating.

At step 508, a second electrode is formed over the photovoltaic layer. In accordance with an embodiment herein, the second electrode is formed by coating a second conductive material over the photovoltaic layer. Examples of the second conductive material include, but are not limited to, silver, aluminum, and calcium. Step 508 may, for example, be performed by vapor deposition or screen printing.

As mentioned above, the photovoltaic layer is capable of converting solar energy into electricity. The first electrode and the second electrode are capable of collecting electricity generated by the photovoltaic layer.

At step 510, a transparent member is positioned over the second electrode. Step 510 may, for example, be performed by a pick-and-place unit that picks the transparent member, and aligns and places the transparent member over the second electrode.

At step 512, the base substrate, the first electrode, the nano-porous layer, the photovoltaic layer and the second electrode are encapsulated with a laminate. Step 512 may, for example, be performed by a laminator that laminates various components of the photovoltaic module with the laminate at a prescribed temperature and/or pressure in a vacuum environment. The vacuum environment ensures that no air bubbles are formed within the laminate. The laminate may, for example, be any material that is tolerant to moisture, abrasion, and natural temperature variations.

It should be noted here that steps 502-512 are only illustrative and other alternatives can also be provided where steps are added, one or more steps are removed, or one or more steps are provided in a different sequence without departing from the scope of the claims herein. For example, one or more of the following steps may be added: a step of cleaning and patterning the first electrode before step 504, a step of cleaning, drying and annealing the nano-porous layer before step 506, and a step of drying and heating the photovoltaic layer after step 506.

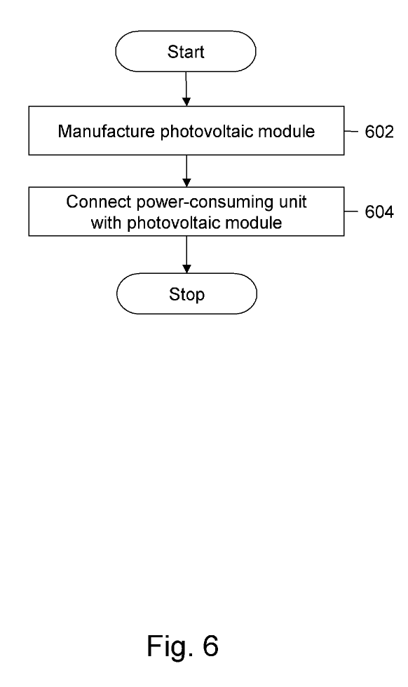

FIG. 6 illustrates a method of manufacturing a system for generating electricity from solar energy, in accordance with an embodiment herein. The method is illustrated as a collection of steps in a logical flow diagram, which represents a sequence of steps that can be implemented in hardware, software, or a combination thereof.

At step 602, a photovoltaic module is manufactured as described in FIGS. 1, 2, 3, 4 and 5. The photovoltaic module may, for example, be similar to photovoltaic module 100.

At step 604, a power-consuming unit is connected with the photovoltaic module electrically. The power-consuming unit is capable of consuming the charge generated by the photovoltaic module. Examples of the power-consuming unit may include a battery or a utility grid. The power-consuming unit may be used to supply power to various devices.

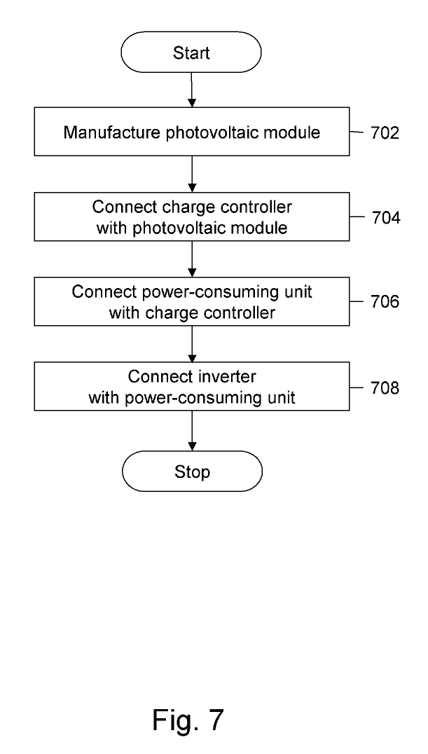

FIG. 7 illustrates a method of manufacturing a system for generating electricity from solar energy, in accordance with another embodiment herein. The method is illustrated as a collection of steps in a logical flow diagram, which represents a sequence of steps that can be implemented in hardware, software, or a combination thereof.

At step 702, a photovoltaic module is manufactured as described in FIGS. 1, 2, 3, 4 and 5. The photovoltaic module may, for example, be similar to photovoltaic module 100.

At step 704, a charge controller is connected with the photovoltaic module electrically. At step 706, a power-consuming unit is connected with the charge controller electrically. The charge controller controls the amount of charge stored in the power-consuming unit. For example, if the amount of charge stored in the power-consuming unit exceeds a first threshold, the charge controller disconnects further charging of the power-consuming unit. Further, if the amount of charge stored in the power-consuming unit decreases to a second threshold, the charge controller reinitiates charging of the power-consuming unit. In an embodiment herein, the first threshold and the second threshold lie between the minimum and the maximum charge-consuming capacity of the power-consuming unit.

Electricity is generated by flow of charge consumed by the power-consuming unit. The power-consuming unit may, for example, produce electricity in a first form. The devices that use the first form of electricity may be connected to the power-consuming unit. However, if the devices do not use the first form of electricity, as generated by the power-consuming unit, at step 708, an inverter is connected with the power-consuming unit electrically. The inverter converts the electricity from the first form, as stored in the power-consuming unit, to a second form. Examples of the first form and the second form include DC and AC.

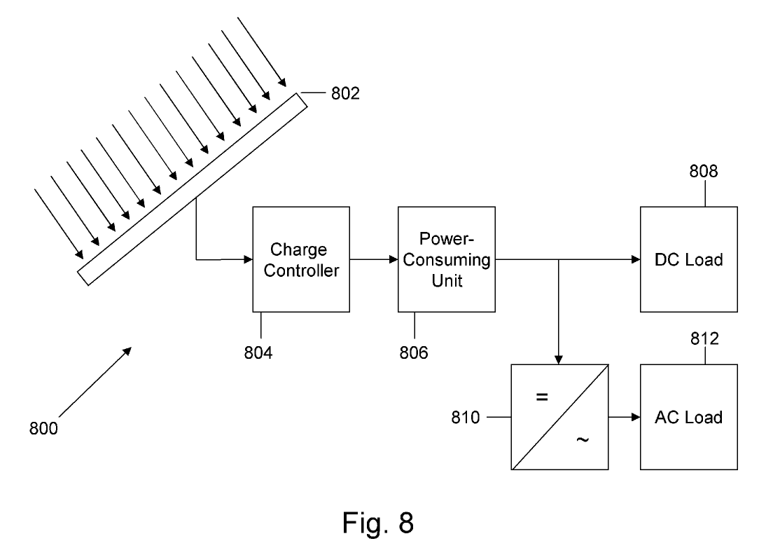

FIG. 8 illustrates a system 800 for generating electricity from solar energy, in accordance with an embodiment herein. System 800 includes a photovoltaic module 802, a charge controller 804, a power-consuming unit 806, a DC load 808, an inverter 810 and an AC load 812.

Photovoltaic module 802 generates electricity from the solar energy that falls on photovoltaic module 802. Photovoltaic module 802 is similar to photovoltaic module 100. Power-consuming unit 806 is connected with photovoltaic module 802 electrically. Power-consuming unit 806 consumes the charge generated by photovoltaic module 802.

In an embodiment herein, power-consuming unit 806 stores the charge generated by photovoltaic module 802. Power-consuming unit 806 may, for example, be a battery. In an embodiment herein, charge controller 804 is connected with photovoltaic module 802 and power-consuming unit 806 electrically, as shown in FIG. 8. Charge controller 804 controls the amount of charge stored in power-consuming unit 806. For example, if the amount of charge stored in power-consuming unit 806 exceeds a first threshold, charge controller 804 discontinues further charging of power-consuming unit 806. Similarly, if the amount of charge stored in power-consuming unit 806 decreases to a second threshold, charge controller 804 reinitiates charging of power-consuming unit 806. In an embodiment herein, the first threshold and the second threshold lie between the maximum and the minimum charge-consuming capacity of power-consuming unit 806.

Electricity is generated by flow of charge consumed by power-consuming unit 806. Power-consuming unit 806 may, for example, produce electricity in a first form. In an embodiment herein, the first form is DC that can be utilized by DC load 808, as shown in FIG. 8. DC load 808 may, for example, be a device that operates on DC.

Inverter 810 is connected with power-consuming unit 806 electrically. Inverter 810 converts electricity from the first form to a second form that is required by AC Load 812. AC load 812 may, for example, be a device that operates on AC. Accordingly, inverter 810 converts DC into AC.

System 800 may be implemented at a roof top of a building, for home or office use. Alternatively, system 800 may be implemented for use with stand-alone electrical devices, such as automobiles and spacecraft.

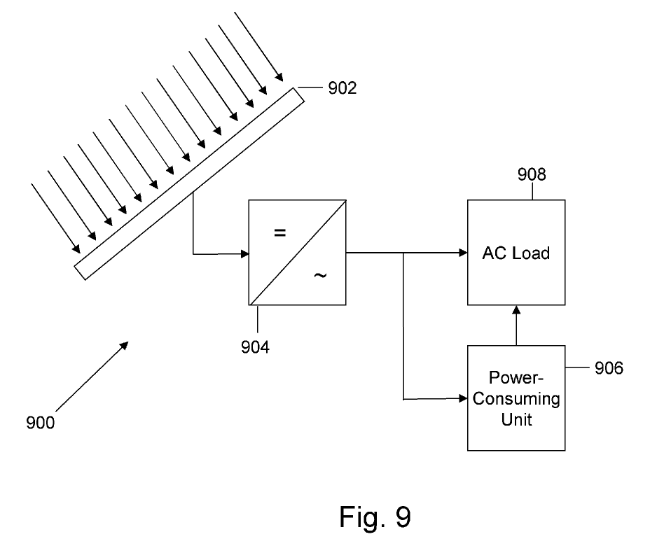

FIG. 9 illustrates a system 900 for generating electricity from solar energy, in accordance with another embodiment herein. System 900 includes an array of photovoltaic modules 902, an inverter 904, a power-consuming unit 906, and an AC load 908.

As mentioned above, inverter 904 converts electricity generated by the array of photovoltaic modules 902 from a first form to a second form. With reference to FIG. 9, electricity in the second form is utilized by power-consuming unit 906. Power-consuming unit 906 may, for example, be a utility grid.

For example, the array of photovoltaic modules 902 may be used to generate electricity on a large scale for grid power supply. Accordingly, electricity in the second form may be supplied to AC Load 908, as shown in FIG. 9.

Embodiments herein provide a photovoltaic module in which a photovoltaic layer of an organic material is formed over a nano-porous layer of an inorganic material. The surface area of the interface between the nano-porous layer and the photovoltaic layer is large. Consequently, charge carrier separation at the interface is higher. This, in turn, enhances the efficiency of the photovoltaic module.

In addition, the size of the nano-pores may be varied as required, for example, by using different inorganic materials, by using different complexing agents and surfactants, and by varying the power and/or frequency of the ultrasonic and/or microwave assistance.

Furthermore, the nano-porous layer is formed by a single-step, simple and inexpensive chemical bath deposition process. This reduces the cost of the photovoltaic module, while making the photovoltaic module easier to manufacture and suitable for mass manufacturing.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

What is claimed as being new and desired to be protected by Letters Patent of the United States is as follows:

1. A photovoltaic module comprising:
a base substrate for providing support;
a nano-porous layer of an inorganic material deposited over said base substrate, said nano-porous layer comprising a plurality of nano-pores;
a photovoltaic layer of an organic material formed over said nano-porous layer, said organic material being deposited into said nano-pores, said photovoltaic layer being capable of converting solar energy into electricity; and
at least two electrodes capable of collecting electricity generated by said photovoltaic layer.

2. The photovoltaic module of claim 1, wherein said inorganic material is selected from the group consisting of Cadmium Sulfide (CdS), Cadmium Telluride (CdTe), Copper Indium Diselenide (CuInSe₂), Copper Indium/Gallium Selenide (CIGS), Stannous Sulfide (SnS), Copper Zinc Tin Sulfide (Cu₂ZnSnS₄), Copper Aluminum Tin Selenide (CuAlSnSe₄), and Lead Selenide (PbSe).

3. The photovoltaic module of claim 1, wherein said organic material is selected from the group consisting of Poly[5,5-bis(3-dodecyl-2-thienyl)-2,2-bithiophene (PQT-12), Poly(3-hexylthiophene) (P3HT), Copper Phthalocyanine (CuPc), Zinc Phthalocyanine (ZnPc), Poly[2-methoxy-5-(3,7-dimethyloctyloxy)]-1,4-phenylene vinylene (MDMO:PPV), and Poly carbazole.

4. The photovoltaic module of claim 1, wherein the thickness of said nano-porous layer ranges from 100 nm to 200 nm, the size of said nano-pores ranges from 100 nm to 200 nm, and the molecular size of said organic material ranges from 100 nm to 200 nm.

5. The photovoltaic module of claim 1 further comprising a transparent member positioned over said photovoltaic layer.

6. The photovoltaic module of claim 1 further comprising a laminate encapsulating said base substrate, said nano-porous layer, said photovoltaic layer and said at least two electrodes.

7. A photovoltaic module system for generating electricity from solar energy, said photovoltaic module system comprising:
a base substrate for providing support;
a nano-porous layer of an inorganic material deposited over said base substrate, said nano-porous layer comprising a plurality of nano-pores;
a photovoltaic layer of an organic material formed over said nano-porous layer, said organic material being deposited into said nano-pores, said photovoltaic layer being capable of converting solar energy into electricity;
at least two electrodes capable of collecting electricity generated by said photovoltaic layer; and
a power-consuming unit adapted to consume charge generated by said photovoltaic module, said power-consuming unit being connected electrically with said photovoltaic module.

8. The photovoltaic module system of claim 7, wherein said inorganic material is selected from the group consisting of Cadmium Sulfide (CdS), Cadmium Telluride (CdTe), Copper Indium Diselenide (CuInSe₂), Copper Indium/Gallium Selenide (CIGS), Stannous Sulfide (SnS), Copper Zinc Tin Sulfide (Cu₂ZnSnS₄), Copper Aluminum Tin Selenide (CuAlSnSe₄), and Lead Selenide (PbSe).

9. The photovoltaic module system of claim 7, wherein said organic material is selected from the group consisting of Poly[5,5-bis(3-dodecyl-2-thienyl)-2,2-bithiophene (PQT-12), Poly(3-hexylthiophene) (P3HT), Copper Phthalocyanine (CuPc), Zinc Phthalocyanine (ZnPc), Poly[2-methoxy-5-(3,7-dimethyloctyloxy)]-1,4-phenylene vinylene (MDMO:PPV), and Poly carbazole.

10. The photovoltaic module system of claim 7, wherein the thickness of said nano-porous layer ranges from 100 nm to 200 nm, the size of said nano-pores ranges from 100 nm to 200 nm, and the molecular size of said organic material ranges from 100 nm to 200 nm.

11. The photovoltaic module system of claim 7 further comprising a charge controller adapted to control the amount of charge consumed by said power-consuming unit, said charge controller being connected electrically with said power-consuming unit and said photovoltaic module.

12. The photovoltaic module system of claim 7 further comprising an inverter adapted to convert electricity from a first form to a second form, wherein electricity is generated by flow of charge consumed by said power-consuming unit, said inverter being connected electrically with said power-consuming unit, and wherein said first form and said second form are selected from the group consisting of an alternating current and a direct current.

13. A method of manufacturing a photovoltaic module, said method comprising:
forming a first electrode over a first surface of a base substrate;
depositing a nano-porous layer of an inorganic material over said first electrode, using a chemical bath deposition, said nano-porous layer comprising a plurality of nano-pores;
forming a photovoltaic layer of an organic material over said nano-porous layer, said organic material being deposited into said nano-pores, said photovoltaic layer being capable of converting solar energy into electricity; and
forming a second electrode over said photovoltaic layer, wherein said first electrode and said second electrode are capable of collecting electricity generated by said photovoltaic layer.

14. The method of claim 13, wherein said depositing said nano-porous layer comprises performing an ultrasonic-assisted chemical bath deposition of said inorganic material over said first electrode.

15. The method of claim 13, wherein said depositing said nano-porous layer comprises performing a microwave-assisted chemical bath deposition of said inorganic material over said first electrode.

16. The method of claim 13, wherein said depositing said nano-porous layer comprises using at least one complexing agent selected from the group consisting of Ethylenediaminetetraacetic acid (EDTA), Sodium Citrate, Hydrazine, Triethylamine, and Triethanolamine.

17. The method of claim 13, wherein said depositing said nano-porous layer comprises:
controlling the thickness of said nano-porous layer and the size of said nano-pores; and
forming said nano-pores with sizes ranging from 100 nm to 200 nm.

18. The method of claim 13, wherein said inorganic material is selected from the group consisting of Cadmium Sulfide (CdS), Cadmium Telluride (CdTe), Copper Indium Diselenide (CuInSe₂), Copper Indium/Gallium Selenide (CIGS), Stannous Sulfide (SnS), Copper Zinc Tin Sulfide (Cu₂ZnSnS₄), Copper Aluminum Tin Selenide (CuAlSnSe₄), and Lead Selenide (PbSe).

19. The method of claim 13, wherein said organic material is selected from the group consisting of Poly[5,5-bis(3-dodecyl-2-thienyl)-2,2-bithiophene (PQT-12), Poly(3-hexylthiophene) (P3HT), Copper Phthalocyanine (CuPc), Zinc Phthalocyanine (ZnPc), Poly[2-methoxy-5-(3,7-dimethyloctyloxy)]-1,4-phenylene vinylene (MDMO:PPV), and Poly carbazole.

20. The method of claim 13 further comprising:
connecting a power-consuming unit with said photovoltaic module electrically, said power-consuming unit being capable of consuming charge generated by said photovoltaic module;
connecting a charge controller with said power-consuming unit and said photovoltaic module electrically, said charge controller being capable of controlling the amount of charge consumed by said power-consuming unit; and
connecting an inverter with said power-consuming unit electrically, said inverter being capable of converting electricity from a first form to a second form, wherein electricity is generated by flow of charge consumed by said power-consuming unit, and wherein said first form and said second form are selected from the group consisting of an alternating current and a direct current.
